(19) United States
(12) Patent Application Publication
(10) Pub. No.: US 2016/0182091 A1
(43) Pub. Date: Jun. 23, 2016

(54) IMPROVED ERROR CONTROL CODING AN DECODING FOR SERIAL CONCATENATED CODES

(71) Applicant: THOMSON LICENSING, Issy les Moulineaux (FR)

(72) Inventor: John Sidney STEWART, Indianapolis, IN (US)

(73) Assignee: Thomson Licensing, Issy les Moulineaux (FR)

(21) Appl. No.: 14/910,105

(22) PCT Filed: Aug. 13, 2014
(86) PCT No.: PCT/US14/50802

§ 371 Date: Feb. 4, 2016

Related U.S. Application Data
(60) Provisional application No. 61/869,148, filed on Aug. 23, 2013.

(51) Int. Cl. H03M 13/29; H03M 13/15; H03M 13/00; H03M 13/11

(52) U.S. Cl. CPC H03M 13/2906; H03M 13/1102; H03M 13/152; H03M 13/6552

(57) ABSTRACT

A broadcast TV signal is a DVB-T2 based system. The DVB-T2 transmitter offsets the BCH codeword with respect to the LDPC codeword, such that, e.g., the first half of the BCH codeword is contained in one LDPC codeword and the second half of the BCH codeword is contained in the next LDPC codeword.

### CROSS-REFERENCE TO RELATED APPLICATIONS

This application claims the benefit of U.S. Provisional Application Ser. No. 61/869,148, filed Aug. 23, 2013, which is incorporated by reference herein in its entirety.

### BACKGROUND OF THE INVENTION

The present invention generally relates to communications systems and, more particularly, to a television (TV) system.

In a Digital Video Broadcast Terrestrial (DVB-T) style system such as DVB-T2, the DVB-T2 Forward Error Correction (FEC) consists of two serial FEC types. These are a Low Density Parity Check (LDPC) code followed by a Bose-Chaudhuri-Hocquenghem multiple error correction binary block (BCH) code. The LDPC code is known to have an error floor where even at relatively high Signal-to-Noise Ratio (SNR), it allows a few errors to exit the decoding process. The purpose of the BCH code, which is a fairly weak code, is to clean up these few errors produced by the LDPC coding. The combination of the two codes in series provides a performance that is very close to the Shannon capacity limit Depending upon the code rates used, the performance is approximately 1 dB away from the theoretical limit over the AWGN channel. The block boundaries of these FEC codes are aligned.

There are several ways to improve the performance for the AWGN channel. For example, it is known that there are several discovered LDPC codes that are <0.01 dB away from theoretical. Unfortunately, these codes are not easy to encode/decode. The LDPC code chosen for the DVB-X2 standards (e.g., DVB-T2, DVB-C2, DVB-S2) was chosen in part due to its semi-regular structure that allows a consumer grade encoder/decoder to be built. However, even if one is restricted to the existing DVB-X2 codes, there are still several ways to improve the performance of the codes.

Traditionally, the LDPC decoder is constructed as a soft-information decoder, and the BCH decoder is built as a hard-information decoder. The output of the BCH decoder has one of two possible outcomes. One outcome occurs when the number of incorrect bits is less than the correction capability of the BCH code. If this occurs, then all of the errors are corrected. The other possible outcome is when the number of errors exceeds the capability of the BCH code. In this case, the decoder cannot correct any of the errors, but can indicate with high probability that the data has errors.

One way to improve on this design is to change the BCH decoder over to a soft-information decoder. The output of a soft-information BCH decoder is a reliability indicator for each bit being decoded. The reason that this is helpful is that if the correction capability of the BCH code is exceeded, the information about the reliability of the bits can be fed back to the previous LDPC decoder. This creates a decoding loop (similar to a simplistic turbo code) between the LDPC decoder and the BCH decoder. On each iteration, the reliability of the decoded bits may improve. There are several published papers that use this technique to improve the performance of the concatenated LDPC/BCH code. Unfortunately, the complexity of a soft-information BCH decoder is very high and therefore expensive to build.

### SUMMARY OF THE INVENTION

In view of the above, existing LDPC and BCH decoders are arranged in a way that allows for some iteration between the two decoders to improve performance without using a soft-information BCH decoder. In particular, and accordance with the principles of the invention, it is proposed to offset the block boundaries to allow for better performance using feedback from the BCH code to the LDPC code. This scheme can also be applied to other FEC schemes where there are two or more serial FEC codes.

In an illustrative embodiment, in accordance with the principles of the invention, the broadcast TV signal is a DVB-T2 based system. The DVB-T2 transmitter offsets the BCH codeword with respect to the LDPC codeword, such that, e.g., the first half of the BCH codeword is contained in one LDPC codeword and the second half of the BCH codeword is contained in the next LDPC codeword.

In another illustrative embodiment, in accordance with the principles of the invention, a DVB-T2 receiver receives a DVB-T2 broadcast signal comprising an offset LDPC/BCH scheme. The DVB-T2 receiver comprises an LDPC decoder and a BCH decoder. The LDPC decoder provides an LDPC decoded signal to the BCH decoder, which provides a decoded signal. In accordance with the principles of the invention, the BCH decoded signal is also provided back to the LDPC decoder for iterative decoding.

In view of the above, and as will be apparent from reading the detailed description, other embodiments and features are also possible and fall within the principles of the invention.

### BRIEF DESCRIPTION OF THE DRAWINGS

FIG. 1 shows prior art boundaries between a BCH codeword and an LDPC codeword;

FIG. 2 illustrates an offset boundary between a BCH codeword and an LDPC codeword in accordance with the principles of the invention;

FIG. 3 shows an illustrative DVB-T2 compatible signal format;

FIG. 4 shows an illustrative flow chart for use in a DVB-T2 transmitter in accordance with the principles of the invention;

FIG. 5 shows an illustrative transmitter in accordance with the principles of the invention;

FIG. 6 shows a portion of an illustrative DVB-T2 transmitter in accordance with the principles of the invention;

FIG. 7 shows an illustrative embodiment of a device, or receiver, in accordance with the principles of the invention;

FIG. 8 shows a portion of an illustrative DVB-T2 receiver in accordance with the principles of the invention;

FIG. 9 shows an illustrative flow chart for use in a DVB-T2 receiver in accordance with the principles of the invention;

FIG. 10 shows an illustrative error sequence in the prior art of FIG. 1;

FIG. 11 shows an illustrative error sequence in accordance with the principles of the invention;

FIG. 12 shows the performance of the normal decoding and the half-shift iterative decoding under an AWGN channel;

FIG. 13 shows a portion of another illustrative DVB-T2 receiver in accordance with the principles of the invention;

FIG. 14 illustrates a block interleaver with a depth of 4 in accordance with the principles of the invention;

FIG. 15 shows an estimate of the performance of a block interleaver; and

FIG. 16 shows an illustrative DVB-T2 L1 pre-signaling table in accordance with the principles of the invention.

### DETAILED DESCRIPTION

Other than the inventive concept, the elements shown in the figures are well known and will not be described in detail. For example, other than the inventive concept, a set-top box or digital television (DTV) and the components thereof, such as a front-end, Hilbert filter, carrier tracking loop, video processor, remote control, etc., are well known and not described in detail herein. In addition, other than the inventive concept, familiarity with networking, OFDM and current and proposed recommendations for TV standards is assumed and not described herein. Such as, e.g., NTSC (National Television Systems Committee); PAL (Phase Alternation Lines); SECAM (SEquential Couleur Avec Memoire); ATSC (Advanced Television Systems Committee) (e.g., ATSC Standard: Program and System Information Protocol for Terrestrial Broadcast and Cable (PSIP) Document A/65); Chinese Digital Television System (GB) 20600-2006; Digital Video Broadcasting (DVB-T2) and DVB-H. In particular, familiarity with the following DVB-T2 standards is assumed: ETSI EN 302 755 V1.3.1: Digital Video Broadcasting (DVB); Frame structure channel coding and modulation for a second generation digital terrestrial television broadcasting system (DVB-T2); ETSI TS 108 831 V1.2.1: Digital Video Broadcasting (DVB); Implementation Guidelines for a second generation digital terrestrial television broadcasting system (DVB-T2); ETSI TS 102 992: Digital Video Broadcasting (DVB); Structure and modulation of optional transmitter signatures (T2-TX-SIG) for use with the DVB-T2 second generation digital terrestrial television broadcasting system; and ETSI EN 300 468: Digital Video Broadcasting (DVB); Specification for Service Information (SI) in DVB systems. It should also be noted that the inventive concept may be implemented using conventional programming techniques, which, as such, will not be described herein. Finally, like-numbers on the figures represent similar elements.

As noted above, existing LDPC and BCH decoders are arranged in a way that allows for some iteration between the two decoders to improve performance without using a soft-information BCH decoder. In particular, and accordance with the principles of the invention, it is proposed to offset the block boundaries to allow for better performance using feedback from the BCH code to the LDPC code. This scheme can also be applied to other FEC schemes where there are two or more serial FEC codes.

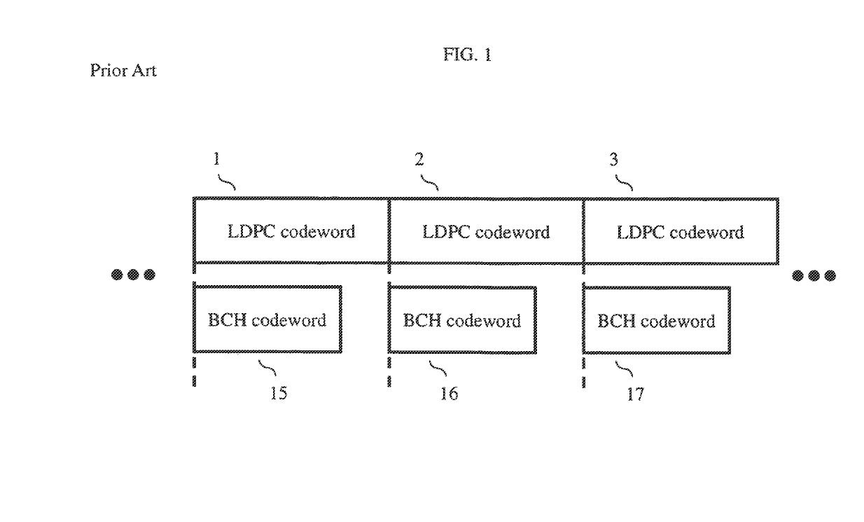

Illustratively, the boundary of the BCH code word is simply shifted in the transmitter so that it does not align with the LDPC code word. Currently, as shown in FIG. 1, each BCH codeword is entirely contained within a single LDPC codeword. In particular, a sequence of received LDPC codewords 1, 2 and 3 completely contain BCH codewords 15, 16 and 17, respectively. When a hard-information BCH decoder is used, this does not allow for any feedback to the LDPC decoder. Either the BCH codeword can be decoded correctly or it cannot be decoded and is flagged as an incorrect codeword.

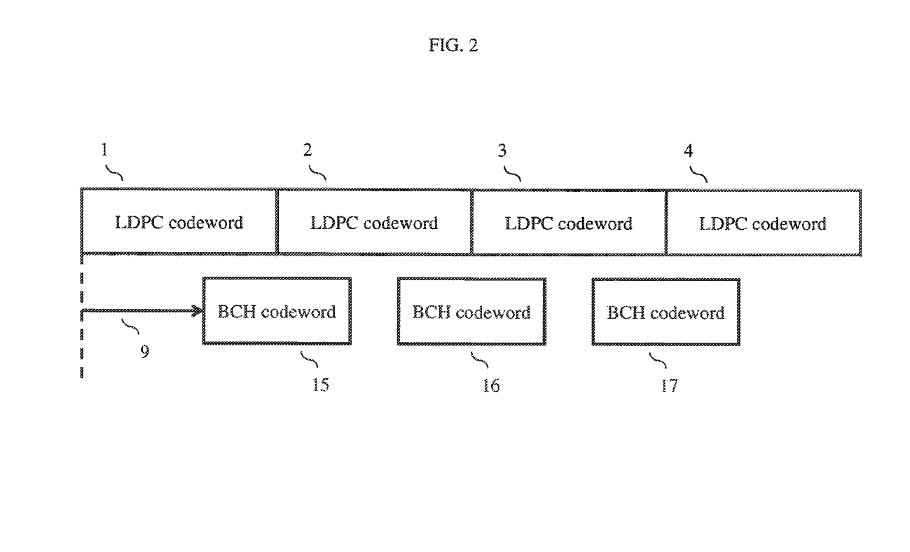

However, and in accordance with the principles of the invention, the BCH codeword is offset such that, e.g., the first half of the BCH codeword is contained in one LDPC codeword and the second half of the BCH codeword is contained in the next LDPC codeword. This is shown in FIG. 2. For example, each BCH codeword is offset in the transmitter by, e.g., offset 9, such that the first half of BCH codeword 15 is contained in LDPC codeword 1 and the second half of BCH codeword 15 is contained in LDPC codeword 2. Similarly for BCH codewords 16 and 17 with respect to LDPC codewords 2, 3 and 4. The delay between the BCH codeword and the LDPC codeword can be performed in the transmitter using a fixed delay device such as a memory. The additional memory required is one half of a BCH codeword. The LDPC encoder needs the second half of the previous BCH codeword as well as the first half of the current BCH codeword. However, it should be noted that if the errors in the LDPC codewords have a normal distribution (are evenly distributed), then it should not matter where the BCH codeword boundaries occur with respect to the LDPC codewords.

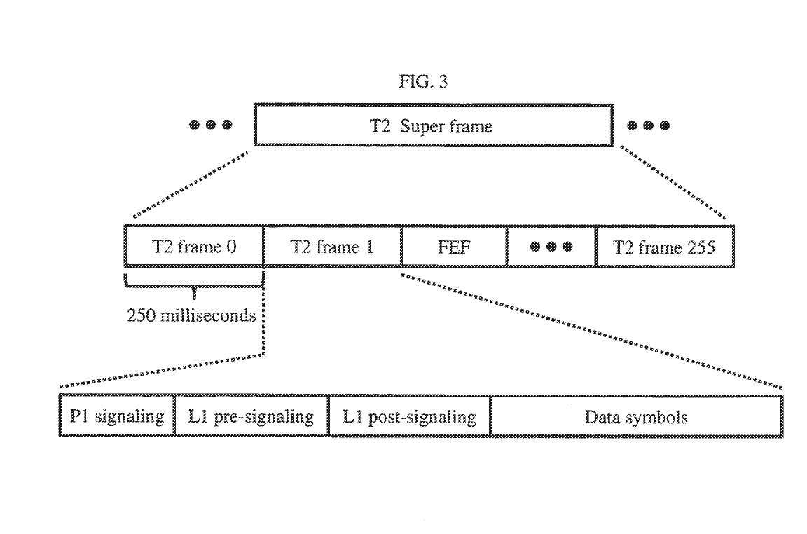

An illustrative embodiment, in accordance with the principles of the invention, will now be described in the context of a DVB-T2 system. In current DVB-T2 style systems, there is a preamble that is sent before the main data symbols. A DVB-T2 compatible signal format is illustrated in FIG. 3. As shown in FIG. 3, a DVB-T2 compatible signal format is comprised of a sequence of super frames (as represented by the ellipses), each super frame comprising, at most, 256 T2 frames (numbered from 0 to 255). Each T2 frame is, at most, 250 milliseconds long. In addition, each superframe may also comprise one, or more, Future Extension Frames (FEFs). Each T2 frame carries P1 signaling, L1 pre-signaling, L1 post signaling and data symbols for the physical layer pipes (PLPs) (e.g., see ETSI EN 302 755 and ETSI TS 102 831). The PLPs carry the services, e.g., programs for viewing by a user. As illustrated in FIG. 3, the L1 pre-signaling data is transmitted as a part of the preamble in the initial part of a T2 frame before the data symbols.

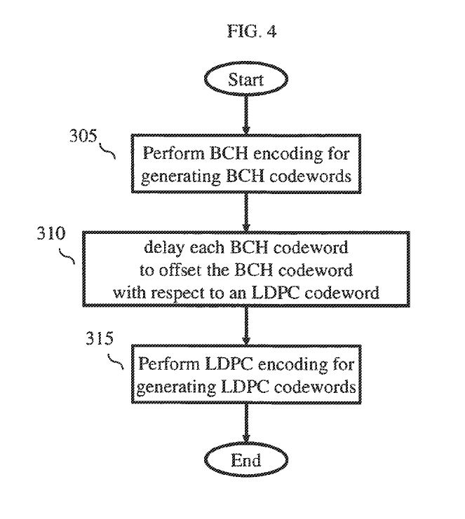

An illustrative flow chart for use in a DVB-T2 transmitter is shown in FIG. 4. Only that portion relevant to the inventive concept is shown. In step 305, the DVB-T2 transmitter performs BCH encoding for generating BCH codewords. In step 310, DVB-T2 transmitter delays each generated BCH codeword with respect to an LDPC codeword. Illustratively, the delay is such that one half of the BCH codeword is in a current LDPC codeword and the other half of the BCH codeword is in the following LDPC codeword as illustrated in FIG. 2. However, this is simply an illustration and other size offsets can be used. Finally in step 315, the DVB-T2 transmitter performs LDPC encoding for generating LDPC codewords.

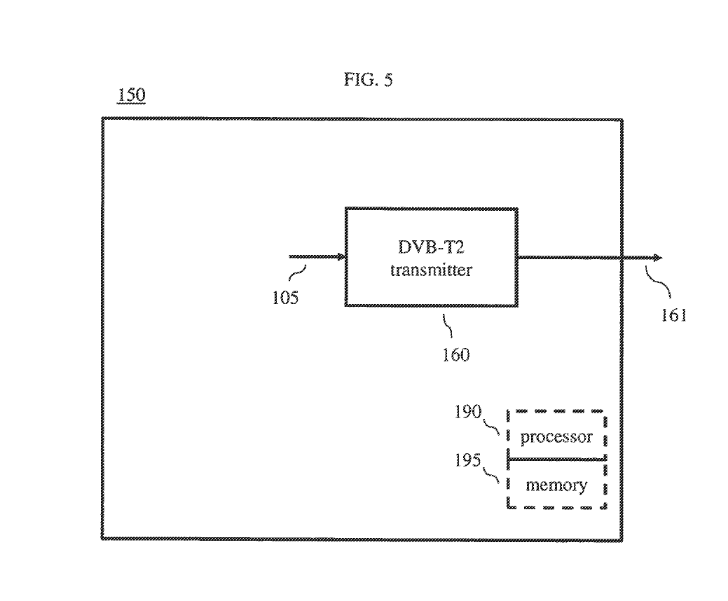

Referring now to FIG. 5, an illustrative embodiment of a transmitter 150 in accordance with the principles of the invention is shown. Only that portion of transmitter 150 relevant to the inventive concept is shown, e.g., the processing of data 105. The later represents a sequence of information for T2 frames, i.e., the P1 signaling, L1 pre-signaling and data symbols as illustrated in FIG. 3. Other than the inventive concept, transmitter 150 conforms to DVB-T2 standards, e.g., see the DVB-T2 implementation guidelines described in ETSI TS 102 831 and ETSI EN 302 755. Transmitter 150 is representative of any processor-based platform for transmission of a signal. In this regard, transmitter 150 includes one, or more, processors and associated memory as represented by processor 190 and memory 195 shown in the form of dashed boxes in FIG. 5. In this context, computer programs, or software, (e.g., representing the flow chart, e.g., of FIG. 4) are stored in memory 195 for execution by processor 190. The latter is representative of one, or more, stored-program control processors and these do not have to be dedicated to the transmitter function, e.g., processor 190 may also control other functions of transmitter 150. Memory 195 is representative of any storage device, e.g., random-access memory (RAM), read-only memory (ROM), etc.; may be internal and/or external to transmitter 150; and is volatile and/or non-volatile as necessary. Transmitter 150 comprises DVB-T2 transmitter 160. The latter is representative of the coding, framing, modulation, etc., in DVB-T2. For this example, it is assumed that an 8K carrier mode is used. Any or all of these components may be implemented in software as represented by processor 190 and memory 195. Finally, DVB-T2 transmitter 160 offsets each BCH codeword with respect to an LDPC codeword in accordance with the principles of the invention and provides a signal 161 for transmission via an antenna (not shown).

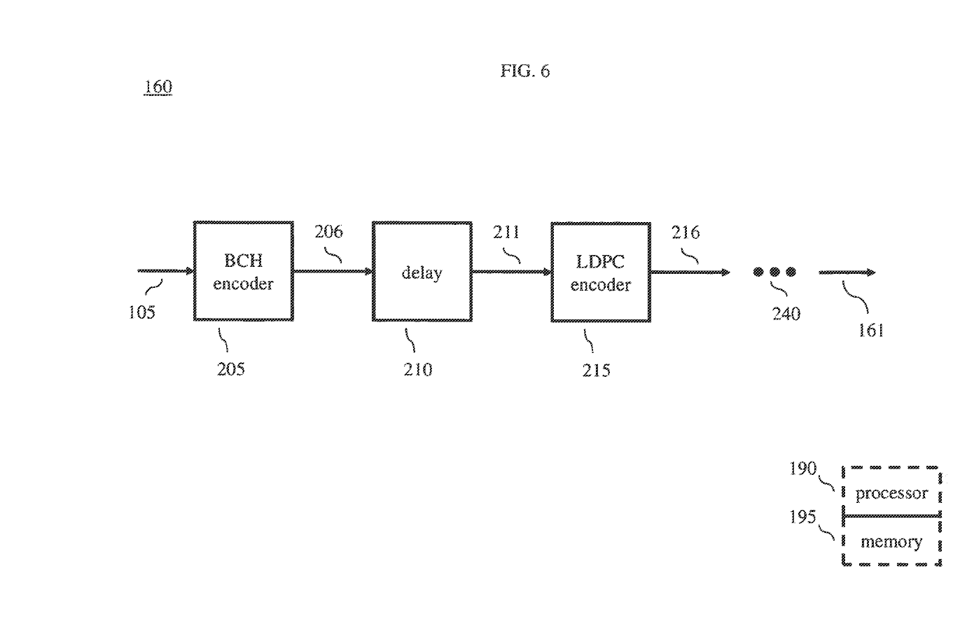

Turning now to FIG. 6 an illustrative embodiment, in accordance with the principles of the invention, is shown for offsetting each BCH codeword with respect to an LDPC codeword. Only that portion of DVB-T2 transmitter 160 relevant to the inventive concept is shown. DVB-T2 transmitter 160 comprises BCH encoder 205, delay element 210 and LDPC encoder 215. As noted above for FIG. 5, one, or more, of the functions of FIG. 6 can be implemented in software via processor 190 and memory 195. BCH encoder 205 receives data 105 and generates BCH codewords 206. Each BCH codeword 206 is then delayed by delay element 210 to provide delayed BCH codewords 211. As noted above, the delay is illustratively such that one half of the BCH codeword is in a current LDPC codeword and the other half of the BCH codeword is in the following LDPC codeword as illustrated in FIG. 2. However, this is simply an illustration and other size offsets can be used. Delay element 210 is illustratively a memory, where the size of the memory is one half of a BCH codeword. LDPC encoder 215 LDPC encodes the delayed BCH codewords 211 to provide coded data 216. The coded data 216 is further processed by DVB-T2 transmitter 160 as known in the art (as represented by ellipses 240) to provide signal 161 for transmission via an antenna (not shown).

By offsetting the BCH codewords and the LDPC codewords in the DVB-T2 transmitter, a simple feedback system can be implemented in a DVB-T2 receiver to improve the performance without using a soft-information BCH decoder.

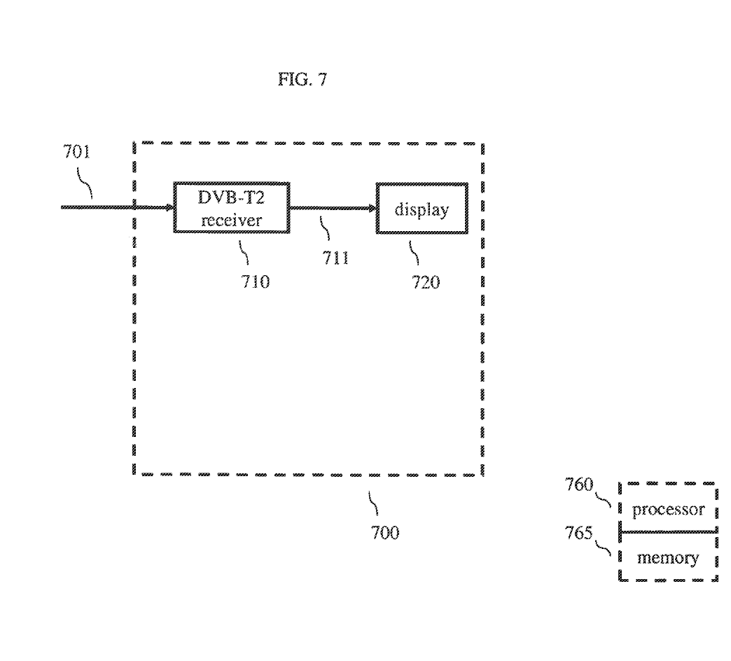

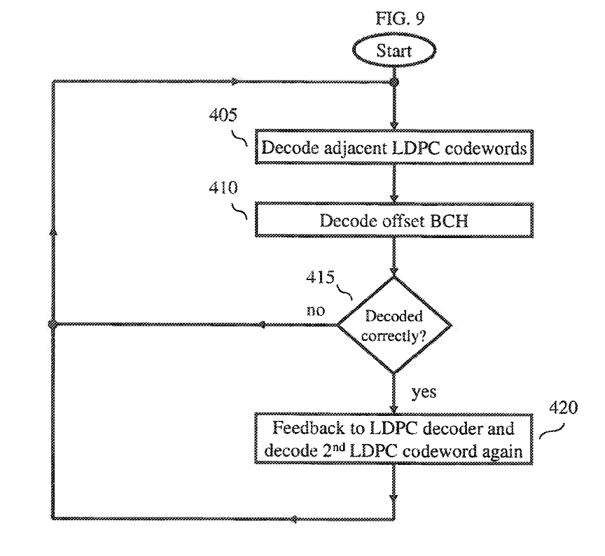

A high-level block diagram of an illustrative device, or receiver, in accordance with the principles of the invention is shown in FIG. 7. Device 700 (e.g., a television) includes a DVB-T2 receiver 710 and a display 720. DVB-T2 receiver 710 receives a broadcast DVB-T2 signal 701 (e.g., via an antenna not shown) for processing to recover therefrom, e.g., an HDTV (high definition TV) video signal for application to display 720 for viewing video content thereon. In accordance with the principles of the invention, DVB-T2 receiver 710 iteratively decodes the received LDPC and BCH codewords without using a soft-information BCH decoder. Device 700 is a processor-based system and includes one, or more, processors and associated memory as represented by processor 760 and memory 765 shown in the form of dashed boxes in FIG. 7. In this context, computer programs, or software, (e.g., representing the flow chart of FIG. 9) are stored in memory 765 for execution by processor 760. As noted, processor 760 is representative of one, or more, stored-program control processors and these do not have to be dedicated to any one particular function of device 700, e.g., processor 760 may also control other functions of the device. Memory 765 is representative of any storage device, e.g., random-access memory (RAM), read-only memory (ROM), etc.; may be internal and/or external to the device; and is volatile and/or non-volatile as necessary.

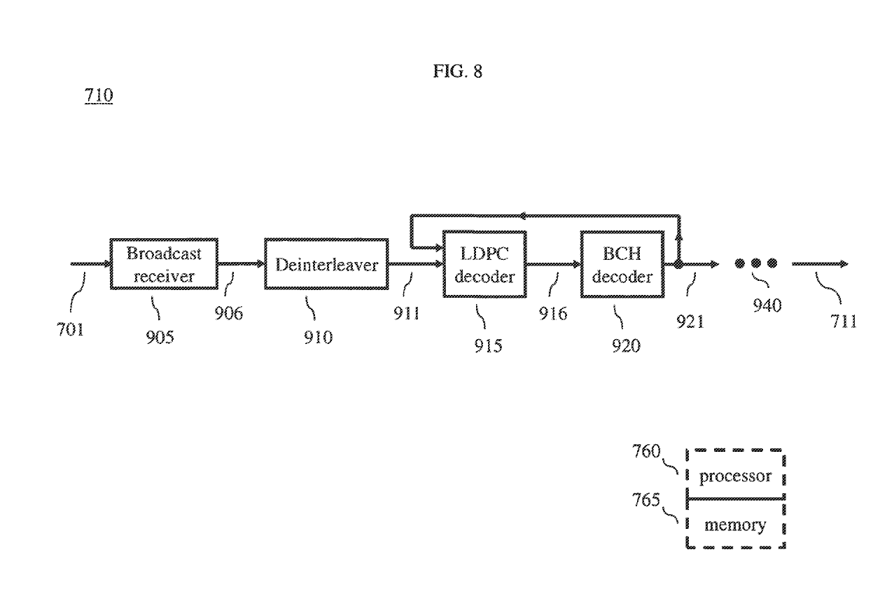

Turning now to FIG. 8 an illustrative embodiment, in accordance with the principles of the invention, is shown for iteratively decoding the received LDPC and BCH codewords without using a soft-information BCH decoder. Only that portion of DVB-T2 receiver 710 relevant to the inventive concept is shown. DVB-T2 receiver 710 comprises broadcast receiver 905, deinterleaver 910, LDPC decoder 915 and BCH decoder 920. As noted above for FIG. 7, one, or more, of the functions of FIG. 8 can be implemented in software via processor 760 and memory 765. Broadcast receiver 905 receives a DVB-T2 broadcast signal from an rf channel and downconverts the signal to provide a demodulated signal 906. Demodulated signal 906 is applied to deinterleaver 910. The latter provides a deinterleaved signal 911 to LDPC decoder 915 in accordance with the above-noted DVB-T2 standard. In accordance with the principles of the invention, the received DVB-T2 signal includes an offset LDPC/BCH scheme as described above (e.g., as illustrated in FIG. 2). LDPC decoder 915 provides an LDPC decoded signal 916 to BCH decoder 920, which provides a decoded signal 921. In accordance with the principles of the invention, the BCH decoded signal 921 is also provided to LDPC decoder 915 for iterative decoding (described below). The decoded signal 921 may be further processed by DVB-T2 receiver 710 as known in the art (as represented by ellipses 940) from which, e.g., an HDTV video signal is recovered for application to display 720 for viewing video content thereon.

An illustrative flowchart for use in a DVB-T2 receiver in accordance with the principles of the invention is shown in FIG. 9. The flowchart will be described in the context of FIG. 2. The decoding occurs as follows. In step 405, processor 760 decodes adjacent LDPC codewords as represent by LDPC codewords 1 and 2 of FIG. 2. In step 410, processor 760 decodes the offset BCH codeword contained in the adjacent LDPC codewords. As illustrated in FIG. 2, the offset BCH codeword is BCH codeword 15. In step 415, processor 760 checks if the BCH codeword was decoded correctly. If the BCH codeword was not decoded correctly, processor 710 begins decoding the next two adjacent LDPC codewords, which in this example would be LDPC codewords 2 and 3, etc. However, if the BCH codeword was decoded correctly, then processor 760 feedsback the corrected bits to the LDPC decoder to decode the second LDPC codeword again. In other words, if BCH codeword 15 was decoded correctly, then the corrected bits can be substituted into the input of the LDPC decoder in place of the received data for the first half of LDPC codeword 2, and LDPC codeword 2 can be decoded for a second time. This reduces the number of bit errors for both the first half and more importantly the second half of LDPC codeword 2. After the second LDPC codeword is decoded again, processor 710 again begins the process over for the next two adjacent codewords, which, as noted just above, are LDPC codewords 2 and 3, etc. In this case LDPC codeword 2 has already been decoded at least once, so now LDPC codeword 3 is also decoded in step 405. If BCH codeword 15 was correctly decoded previously, then BCH codeword 16 will have a higher probability of being decoded correctly in step 410 as the second iteration of LDPC codeword 2 reduced the number of errors in the BCH codeword. This decoding sequence continues with the LDPC codewords being re-decoded for each correct BCH codeword that is decoded.

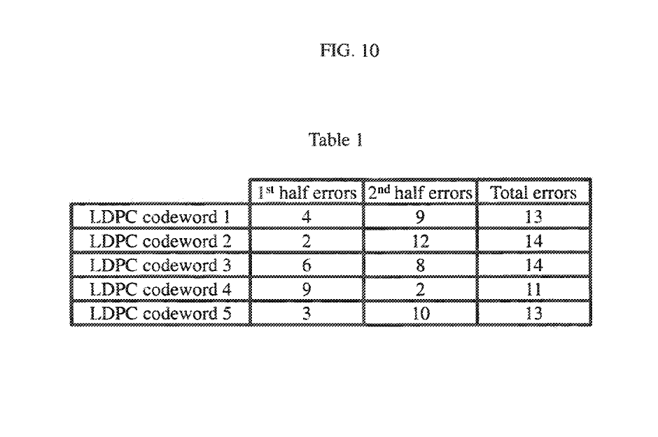

As further illustration, the inventive concept is compared to the prior art. For example, consider a data steam in the prior art has the error sequence illustrated in Table 1, of FIG. 10, after LDPC decoding and assume that the BCH decoder is able to correct 12 bit errors. For this sequence of errors, the current aligned prior art LDPC/BCH setup shown in FIG. 1 would allow for only 1 of the BCH codewords to be decoded correctly (LDPC codeword 4 as it has less than 12 or fewer errors).

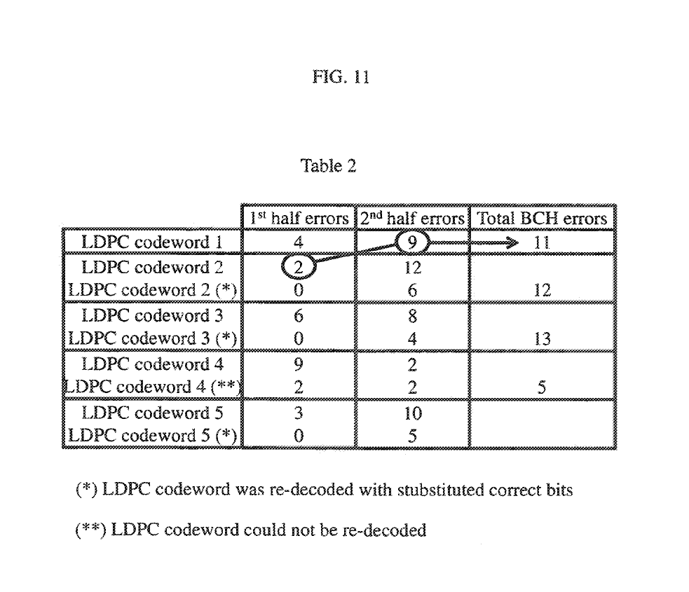

Now consider the case of the offset LDPC/BCH scheme in accordance with the principles of the invention as illustrated in Table 2 of FIG. 11. In accordance with the principles of the invention, each BCH codeword is spread over two LDPC codewords. As shown in FIG. 11, each BCH codeword is constructed by taking the last half of an LDPC codeword and the first half of the next LDPC codeword. In Table 2, the number of errors in each half of the LDPC code word is shown. For example, LDPC codeword 1 has 4 errors in its first half and 9 errors in its second half. LDPC codeword 2 has 2 errors in its first half and 12 errors in its second half. The first BCH codeword that is considered is the one that consists of the second half of LDPC codeword 1 and the first half of LDPC codeword 2. The total BCH errors for this BCH codeword is therefore (9+2)=11 errors as shown in the total BCH errors column of Table 2. Since the BCH decoder can correct 12 errors or less, this BCH codeword is correctly decoded and all of the correct bits for the first half of LDPC codeword 2 are known. Now, if no iterative decoding is being performed between the LDPC decoder and BCH decoder, then the corrected BCH codeword can be sent out and decoding continues. However, if iterative decoding is being performed between the BCH decoder and the LDPC decoder, then after decoding a BCH codeword all of the correct bits for that BCH codeword are known. These can then be substituted back into the LDPC decoder for re-decoding the LDPC codeword. In this example, the BCH codeword consisting of the second half of LDPC codeword 1 and the first half of LDPC codeword 2 is correctly decoded. These correctly decoded bits can now be substituted into the first half of LDPC codeword 2 for re-decoding that LDPC codeword. Since the entire LDPC codeword is connected together through various parity check equations, this should reduce the number of errors in the second half of LDPC codeword 2. This will help in the decoding of the next BCH codeword.

Turning to Table 2 in more detail, the first BCH codeword consists of the second half of LDPC codeword 1 and the first half of LDPC codeword 2. The total errors in this BCH codeword is 11, which can be correctly decoded. Originally LDPC codeword 2 had 2 errors in its first half and 12 errors in its second half. After re-decoding, LDPC codeword 2 has 0 errors in its first half and 6 errors in its second half. This is shown by the two lines for LDPC codeword 2 in Table 2. The first line is the original and the second line is after re-decoding.

The next BCH codeword consists of the second half of LDPC codeword 2 and the first half of LDPC codeword 3. This BCH codeword has 12 total errors (note is would have had 12+6=18 errors if LDPC codeword 2 was not re-decoded). This BCH codeword can be correctly decoded. This means that LDPC codeword 3 can be improved. It originally had 6 errors in the first half and 8 errors in the second half. After re-decoding, it has 0 errors in the first half and 4 errors in the second half.

The next BCH codeword consists of the second half of LDPC codeword 3 and the first half of LDPC codeword 4. This BCH codeword has (4+9)=13 errors. The BCH decoder cannot decode this BCH codeword since it has more than 12 errors, so there is no need for LDPC re-decoding.

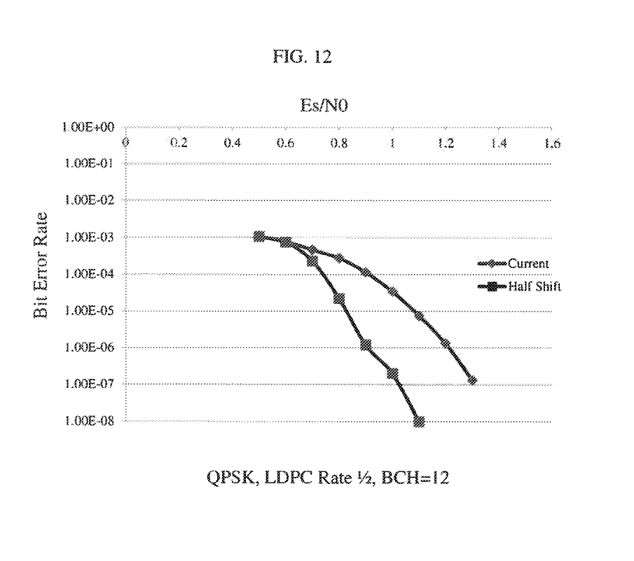

The next BCH codeword consists of the second half of LDPC codeword 4 and the first half of LDPC codeword 5. This BCH codeword has (2+3)=5 errors. This BCH codeword can be decoded and the correct data substituted back into LDPC codeword 5 for re-decoding. That is the end of the sequence. The basic idea is that if a BCH codeword can be decoded, the correct data can be substituted back into the LDPC codeword which can be re-decoded. This will hopefully help the next BCH codeword. In this case, LDPC codewords 2, 3, and 5 can be LDPC decoded for a second time with improved error performance. This allows several more BCH codewords to be decoded than could in the previous example. Simulations for the Rate ½ LDPC+12 error correcting BCH code show an improvement of about 0.35 dB in performance. Since the code is already only about 1 dB from theoretical, this improvement is quite substantial, considering the minimal change required. FIG. 12 shows the performance of the normal decoding and the half-shift iterative decoding under an AWGN channel.

For many current DVB-X2 designs, the changes required to implement this proposal are minimal The iterated decoding does not have to be performed if the extra performance is not required. In this case, only 1 extra buffer is required to hold the additional LDPC codeword. However, this is probably not even necessary as the decoder designs need to take into account the fact that a transport packet may span two LDPC codewords and therefore already requires the extra buffer after decoding. There would be some extra hardware to substitute the decoded BCH codeword information back into the input of the LDPC decoder, but this would be minimal Also, the number of iterations of the LDPC decoder could be controlled so that the total number of iterations performed is the same or slightly more than is already done (usually about 50). In addition, with a slight increase in complexity, the decoding effort can be reduced further. For example, a BCH codeword can attempt to be decoded. Only if it could not be decoded, would the LDPC decoder be run for a second time using corrected bits from the previous BCH codeword.

Finally, this scheme allows for some additional performance improvements but with an increase in complexity. The described decoding scheme is a feed-forward method. This can also be extended to work in the reverse direction. For instance if a BCH codeword could not be decoded, but the next one is able to be decoded, then the current BCH codeword could be used to replace the second half of the previous LDPC codeword which could then be re-iterated. This could possibly help the previous BCH codeword which now may be correctly decoded. This feedback could continue to be applied in the reverse time direction depending upon how many previous codewords are stored.

As noted above, the DVB-T2 FEC consists of two serial FEC types. These are an LDPC code followed by a BCH code. In accordance with another principle of the invention, a block interleaver is added between the LDPC and the BCH code. This allows the output from correctly decoded BCH blocks to be fed back to the LDPC input. This process is iterated to improve the performance of the FEC. This scheme can also be applied to other FEC schemes where there are two or more serial FEC codes.

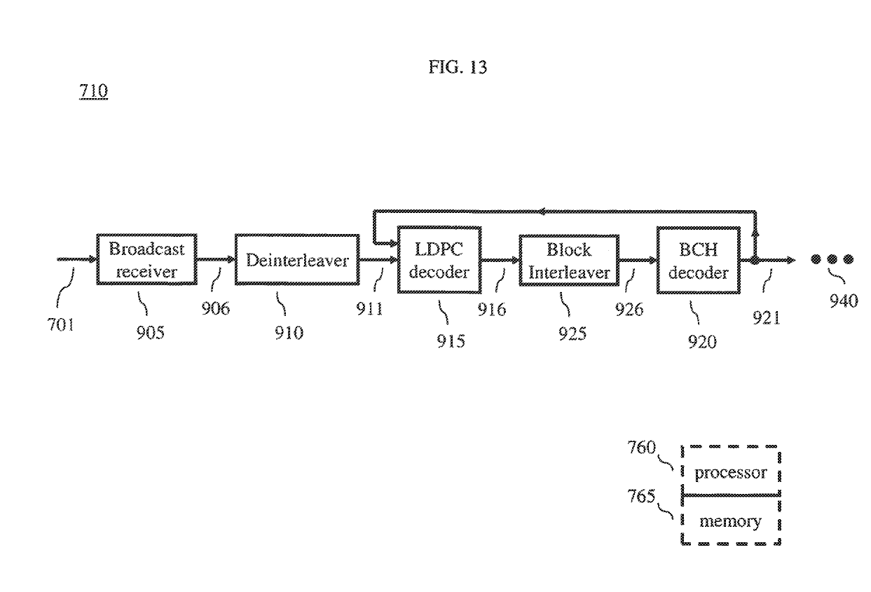

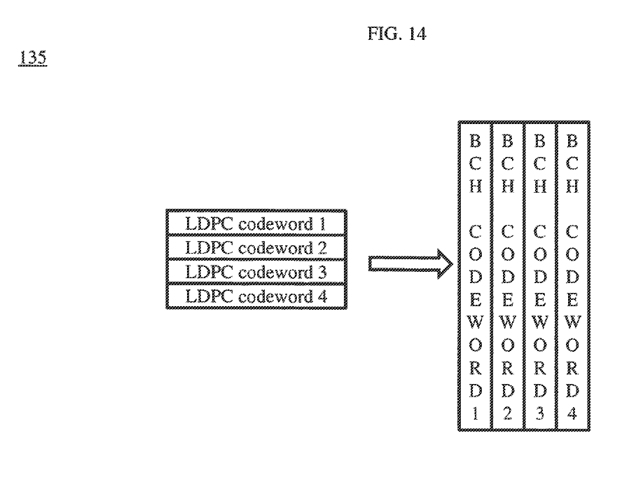

The idea involves inserting a simple interleaver between the LDPC and BCH decoder as shown in FIG. 13. A block interleaver 925 is placed between LDPC decoder 191 and BCH decoder 920. The interleaving depth can be very small (e.g., 2) or larger. FIG. 14, shows a further illustration of block interleaver 925 with a depth of 4. The LDPC codewords are stored row-wise, and the BCH codewords are read out column-wise. As discussed earlier, if the errors within the LDPC codeword are evenly distributed, it should not matter how they are divided up to produce the BCH codewords. The interleaver allows for an iterated decoding process between the BCH decoder and the LDPC decoder as shown in FIG. 13. One nice thing about this scheme is that the interleaved data is the hard-information and not the soft-information which reduces the memory requirements. In addition, since this interleaving provides some time interleaving, there may be an opportunity to reduce the time interleaving that happens before the LDPC decoder.

In the example above with the depth 4 interleaver, if any of the 4 BCH codewords can be correctly decoded, the corrected data can be fed back to the LDPC codewords stored in the interleaver where they replace the received data. The LDPC codewords can then be re-iterated with improved performance. This feedback can be continued until no more BCH codewords can be correctly decoded.

One important reason that this simple block interleaver works so well is that it turns out that the error probability for the LDPC decoded bits is not uniform. This appears to be related to the LDPC code construction. For example, the rate ½ code used for DVB-X2 is constructed from several different lengths of parity equations. Some are of length 8 and some are of length 3, and these two lengths are recombined using a length 2 equation. If the LDPC codewords are decoded and then compared with the original codeword, it shows that there are groups of error probabilities. In this case, there are 3 groups. If the first group has a normalized probability of 1, then the second group has a normalized probability of about 2, and the third group of bits has a probability of about 4. These are arranged in the codeword linearly with the lowest error probability being first. This allows the interleaving scheme to perform even better than expected because those BCH codewords constructed from the early portion of the LDPC codewords have fewer errors than those constructed from the later portions of the LDPC codeword.

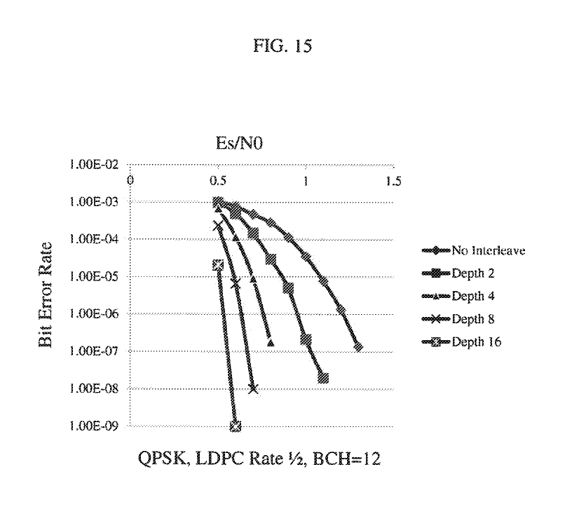

The greater the depth of the interleaver, the better the performance. This is because the larger the number of BCH codewords in the interleaver, the higher the probability that one of the BCH codewords will be correctly decoded which will improve the performance of all the BCH codewords in the interleaver. However, the improvements have diminishing returns and there is a tradeoff between the added performance, the additional memory required for the interleaver, and the increased number of LDPC decodes required. Preliminary testing with rate ½ LDPC+12 error BCH is shown in FIG. 15. The summary is that a depth 2 interleaver provides about 0.25 db improvement, a depth 4 interleaver provides about a 0.5 dB improvement, and a depth 8 interleaver provides about 0.6 dB improvement.

One possibility for DVB-T2 is also to have variable interleaving depending upon the Physical Layer Pipe (PLP). For very low bandwidth, but high reliability data, a larger interleaver could be used. For high bandwidth, low priority data, either no interleaving, or a low level of interleaving, could be used.

As described above, the performance of this concatenated code (LDPC/BCH) can be improved by using an interleaver between the LDPC code and the BCH code. In accordance with the principles of the invention, this performance can be further improved by adding a non-uniform FEC component, e.g., a non-uniform error correction capability for the BCH codewords. (This also applies to the illustrative embodiment of FIG. 8, without the block deinterleaver). As shown in FIG. 14, the LDPC codewords are stored row-wise, and the BCH codewords are read out column-wise. In the normal DVB-T2 operation, each BCH codeword has the same level of error protection. What can happen in this case is that under heavy noise conditions, none of the BCH codewords may be able to be decoded. When this happens, no iteration between the BCH FEC and LDPC FEC can happen as there are no updated corrections from the BCH decoder to be applied to the LDPC decoder.

One improvement to this is to take the same number of correctable bits that are currently used and re-distribute them. For example, if the 4 BCH codewords are each capable of correcting 12 errors, then in total 48 errors can be corrected in a 4×4 interleaver. These 48 errors may be re-distributed among the 4 BCH codewords without affecting the code rate. For example, the BCH codewords could be encoded to allow correction for the following number of errors (20, 12, 8, 8) for BCH codewords 1, 2, 3 and 4 respectively. In this case, the first BCH codeword is able to correct 8 more errors than the original case, while the last two BCH codewords can correct 4 less each. While this may seem a poor tradeoff because only 1 codeword is better while two are worse, the overall effect is to improve the performance. The basic reason is that it increases the chances that at least one BCH codeword can be decoded correctly which can start the iteration process.

For example, in the case where each BCH codeword provides equal, or uniform, error protection of 12 errors, if all 4 codewords have 13 errors, none of the BCH codewords can be correctly decoded. However, in the case of the un-equal error protection, the first codeword can be decoded since, in the above example, the first codeword can correct up to 20 errors. This allows the corrected data to be inserted into the LDPC codewords. When the LDPC codewords are decoded again, the number of errors is reduced and in this example the second BCH codeword now has only 10 errors. This allows the second BCH codeword to be decoded and re-inserted into the LDPC codewords. After LDPC decoding again, the last 2 BCH codewords only have 5 errors each and therefore can be decoded. For this particular case, the un-equal error protection works to get the iterative decoding started which reduces the number of errors which allows the iterations to continue.

As described above, various improvements can be made to the performance of the concatenated code (LDPC/BCH) in a DVB-T2 system. In future transmission systems, it will be common for a receiver to have more than one possible communication channel. For instance, a receiver may have an over the air receiver as well as an Ethernet connection. If data is being received over the air, and an FEC block has errors and is not able to be corrected, one option is to try to get the errored block through the other communication channel. This could for instance be another receiver tuned to the same channel on the local Ethernet network, or it could be a server located on the Internet.

In order for this to be possible, an FEC block must be able to be uniquely identified with the transmission. Unfortunately, for DVB-T2 style systems, this is not currently possible, i.e., in current DVB-T2 style systems, there is not enough information to uniquely identify an FEC block so that it can be replaced. Therefore, and in accordance with the principles of the invention, some additional information is provided to make this unique identification possible.

In current DVB-T2 style systems, data streams are broken up into FEC blocks called BBFRAMES. As defined in the DVB-T2 standard, a BBFRAME is a set of K_{bch} bits which form the input to one FEC encoding process (BCH encoding and LDPC encoding). These BBFRAMES are interleaved and assigned to OFDM frames. Several OFDM frames are then grouped into Superframes. The DVB-T2 standard referenced earlier gives information about where within a superframe the first BBFRAME is located. From this, a counter can be used to uniquely determine within a Superframe the sequential BBFRAME identities (e.g., 4th BBFRAME of a Superframe).

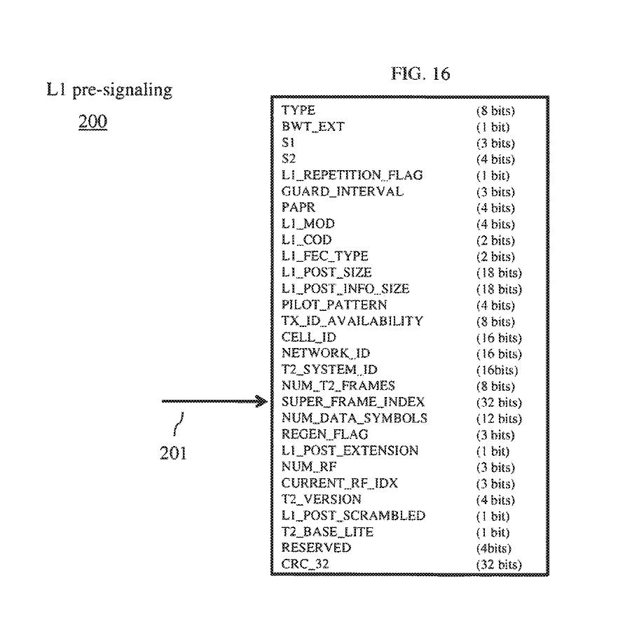

What the current DVB-T2 specification does not provide is a unique identity for the Superframes. In order to request a replacement BBFRAME, the system would need to know both the number of the frame within the Superframe, and a unique identifier for the Superframe. Therefore, and in accordance with the principles of the invention, a 32 bit circular counter is added that is incremented for each Superframe. This information is transmitted within the L1-signaling data of DVB-T2. This is illustrated in FIG. 16. The L1-signaling data is transmitted as a part of the preamble in the initial part of a physical layer frame of DVB-T2. As shown in FIG. 16, the L1 pre-signaling table 200 of DVB-T is modified to now include a SUPER_FRAME_INDEX field with a length of 32 bits as indicated by arrow 201. The length of time between rollovers for the Superframe counter is dependent on many signaling factors but would be on the order of several days. This is long enough to prevent any ambiguities from occurring. As a result, a receiver (e.g., processor 760 of FIG. 8) can now uniquely identify the Superframe upon recovery of the L1 pre-signaling table after LDPC/BCH decoding as illustrated in FIGS. 8 and 13.

Referring now to FIG. 5, DVB-T transmitter 160 is additionally modified for the processing of L1 signaling data as described above. For example, processor 190 suitably modifies the value of the SUPER_FRAME_INDEX in L1 pre-signaling table 200 of FIG. 16. The L1 pre-signaling table 200 is encoded via BCH coder 205 and LDBC coder 215 to provide a coded signal 216. The latter is modulated by DVB-T transmitter 160 as specified in the above-noted DVB-T standard to provide a signal 161 for transmission via an antenna (not shown). The transmitted signal is received by, e.g., the receiver of FIG. 8 or FIG. 13, such that at portions of time the decoded signal 921 represents the received L1 pre-signaling field table.

It should be noted that although the L1 pre-signaling table 200 was described in the context of, e.g., FIGS. 8 and 13, the inventive concept is not so limited and may be applied to a DVB-T2 system without the above-described iterative decoding modifications.

In view of the above, the foregoing merely illustrates the principles of the invention and it will thus be appreciated that those skilled in the art will be able to devise numerous alternative arrangements which, although not explicitly described herein, embody the principles of the invention and are within its spirit and scope. For example, although illustrated in the context of separate functional elements, these functional elements may be embodied in one, or more, integrated circuits (ICs). Similarly, although shown as separate elements, e.g., LDPC decoder 915 and BCH decoder 920 of FIG. 8, any or all of the elements may be implemented in a stored-program-controlled processor, e.g., a digital signal processor, which executes associated software, e.g., corresponding to one, or more, of steps. In addition, although the inventive concept was described in the context of DVB-T2, the inventive concept is also applicable to other communication systems, such as, but not limited to, DVB-C2 and DVB-S2. It is therefore to be understood that numerous modifications may be made to the illustrative embodiments and that other arrangements may be devised without departing from the spirit and scope of the present invention.

1. Apparatus for use in a transmitter, the apparatus comprising:
a Bose-Chaudhuri-Hocquenghem multiple error correction binary block (BCH) coder for BCH coding an input data stream to provide BCH codewords;
a delay element for offsetting each BCH codeword with respect to a boundary of a low density parity check (LDPC) codeword; and
an LDPC coder for LDPC coding the offset BCH codewords for providing LDPC codewords such that a portion of one BCH codeword is conveyed in one LDPC codeword and the remaining portion of the BCH codeword is conveyed by the next LDPC codeword.

2. The apparatus of claim 1, wherein the transmitter transmits a DVB-T2 signal.

3. The apparatus of claim 1, wherein the transmitter transmits data formatted in super frames and further comprising:
a processor for modifying signaling information conveyed by the LDPC codewords to indicate a value for a super frame index.

4. The apparatus of claim 3, wherein the signaling information is an L1 pre-signaling table.

5. A method for use in a transmitter, the method comprising:
coding an input data stream to provide coded output data by using a combination of Bose-Chaudhuri-Hocquenghem multiple error correction binary block (BCH) coding and low density parity check (LDPC) coding such that a portion of one BCH codeword is conveyed in one LDPC codeword and the remaining portion of the BCH codeword is conveyed by the next LDPC codeword; and
transmitting the coded output data.

6. The method of claim 5, wherein the transmitter is a DVB-T2 transmitter.

7. The method of claim 5, wherein the coded output data is formatted for transmission in super frames and wherein the coded output data conveys signaling information to indicate a value for a super frame index.

8. The method of claim 7, wherein the signaling information is an L1 pre-signaling table.

9. Apparatus for use in a receiver, the apparatus comprising:
a demodulator for demodulating a received signal to provide a coded signal;
a low density parity check (LDPC) decoder operative on LDPC codewords of the coded signal; and
a Bose-Chaudhuri-Hocquenghem multiple error correction binary block (BCH) decoder for receiving the output of the LDPC decoder, which represent BCH codewords, and for providing a decoded signal;
wherein each BCH codeword is conveyed in two LDPC codewords; and
wherein the BCH decoder provides decoded BCH codewords back to the LDPC decoder for iteratively decoding the coded signal.

10. The apparatus of claim 9, wherein the BCH decoder only provides corrected BCH codewords back to the LDPC decoder for iteratively decoding the coded signal.

11. The apparatus of claim 9, wherein the receiver is a DVB-T2 receiver.

12. The apparatus of claim 9, wherein the received signal conveys super frames, the apparatus further comprising:
a processor for recovering signaling information conveyed by the received signal to indicate a value for a super frame index.

13. The apparatus of claim 12, wherein the signaling information comprises a forward error correction (FEC) block number and a superframe number, wherein the superframe number identifies a superframe and the FEC block number identifies the location of the FEC block in the identified superframe

14. The apparatus of claim 12, wherein the signaling information is an L1 pre-signaling table.

15. The apparatus of claim 9, wherein at least two adjacent BCH codewords provide different levels of error protection.

16. The apparatus of claim 9, further comprising a block interleaver disposed between the LDPC decoder and the BCH decoder for storing LDPC codewords either row wise or column wise and for providing BCH codewords column wise or row wise respectively.

17. A method for use in a receiver, the method comprising:
demodulating a received signal to provide a coded signal;
low density parity check (LDPC) decoding LDCP codewords of the coded signal for providing an output; and
Bose-Chaudhuri-Hocquenghem multiple error correction binary block (BCH) decoding the output, which represent BCH codewords, and for providing a decoded signal;
wherein each BCH codeword is conveyed in two LDPC codewords; and
wherein the BCH decoder provides decoded BCH codewords back to the LDPC decoder for iteratively decoding the coded signal.

18. The method of claim 17, wherein the BCH decoding step only provides corrected BCH codewords back to the LDPC decoding step for iteratively decoding the coded signal.

19. The method of claim 17 wherein the receiver is a DVB-T2 receiver.

20. The method of claim 17, wherein the received signal conveys super frames, the method further comprising:
recovering signaling information conveyed by the received signal to indicate a value for a super frame index.

21. The method of claim 20, wherein the signaling information comprises a forward error correction (FEC) block number and a superframe number, wherein the superframe number identifies a superframe and the FEC block number identifies the location of the FEC block in the identified superframe.

22. The method of claim 21, further comprising the step of:
transmitting a request for a replacement FEC block using the FEC block number and superframe number.

23. The method of claim 20, wherein the signaling information is an L1 pre-signaling table.

24. The method of claim 17, wherein at least two adjacent BCH codewords provide different levels of error protection.

25. The method of claim 17, further comprising the step of:
block interleaving between the LDPC decoding step and the BCH decoding step for storing LDPC codewords either row wise or column wise and for providing BCH codewords column wise or row wise respectively.
